(19) United States
(12) Patent Application Publication
(10) Pub. No.: US 2009/0236726 A1
(43) Pub. Date: Sep. 24, 2009

(54) PACKAGE-ON-PACKAGE SEMICONDUCTOR STRUCTURE

(75) Inventors: Danny RETUTA, Singapore (SG); Hien Boon TAN, Singapore (SG); Yi Sheng Anthony SUN, Singapore (SG); Librado Amurao GATBONTON, Singapore (SG); Antonio DIMAANO, JR., Singapore (SG)

Correspondence Address: HORIZON IP PTE LTD, 7500A Beach Road, #04-306/308 The Plaza, SINGAPORE 199591, SG

(73) Assignee: UNITED TEST AND ASSEMBLY CENTER LTD., Singapore (SG)

(21) Appl. No.: 12/333,328

(22) Filed: Dec. 12, 2008

Related U.S. Application Data
(60) Provisional application No. 61/012,923, filed on Dec. 12, 2007.

(51) Int. Cl. H01L 23/498; H01L 21/60

(52) U.S. Cl. 257/690; 438/121; 257/686; 438/109; 257/E23.06; 257/E21.506

(57) ABSTRACT

A semiconductor package that includes a substrate having first and second major surfaces is presented. The package includes a plurality of landing pads and a semiconductor die disposed on the first major surface. A molded cap is disposed on the first surface to encapsulate the die and substrate. The landing pads are covered when the cap is molded. Package interconnects are coupled to the landing pads. The package interconnects are exposed by the cap to facilitate package stacking.

### BACKGROUND

The need for miniaturization, increased functionality and portability is driving the demand for 3D packaging in electronic products. Stacked dies package, for example stacked die chip scale package (SCSP), provide solutions to put multiple devices into one package. Nevertheless, only single-sourced devices can be assembled in such technology. Therefore, Package-on-Package (PoP) serves as an alternative as it enables devices from multiple sources to be assembled together. Typically, a PoP consists of a bottom package containing a high performance logic device designed to receive a mating top package which contains high capacity memory devices.

Hence, PoP can benefit end users in terms of saving board space due to its vertical inter-connection feature. However, at the component level, there are some disadvantages or concerns on conventional PoP structure that requires improvement. For example, PoP requires space for placing solder lands used for stacking purposes. This requirement increases the size of the package, which affects the utilization of substrate and subsequently reduces assembly productivity and increase unit cost. Additionally, the stacking of two BGA packages increases the overall height of the package, which may be too thick for a highly integrated memory module within a limited space. Furthermore, some types of PoP, for example quad type package, require air vent on corners of the mold cap. The air vents normally run in between solder pads, which increase pitch. This further increases the size of PoP packages.

From the foregoing discussion, it is desirable to provide an improved PoP semiconductor structure and method of packaging semiconductor devices.

### SUMMARY

A semiconductor package is presented in one embodiment. The package includes a substrate having first and second major surfaces. A plurality of landing pads and a semiconductor die are disposed on the first major surface. A molded cap is disposed on the first surface to encapsulate the die and substrate. The landing pads are covered when the cap is molded. The package further includes package interconnects coupled to the landing pads. The package interconnects are exposed by the cap to facilitate package stacking.

In another embodiment, a method of forming a semiconductor package is disclosed. The method includes providing a substrate with first and second major surfaces and a plurality of landing pads on the first major surface. A die is attached on the first major surface and a cap is formed on the first major surface to encapsulate the die and substrate. The landing pads are covered when the cap is formed. The method further includes providing package interconnects coupled to the landing pads. The package interconnects are exposed by the cap to facilitate package stacking.

A method of forming a semiconductor package is presented in another embodiment. The method includes providing a substrate with first and second major surfaces and a plurality of landing pads on the first major surface. The method further includes attaching a die on the first major surface and forming a cap on the first major surface to encapsulate the die and substrate. The cap includes vias exposing the landing pads. The vias are filled with a conductive material to form package interconnects on the landing pads. Top surfaces of the package interconnects are exposed by the cap to facilitate package stacking.

These and other objects, along with advantages and features of the present invention herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIGS. 1a-c show various embodiments of a die package;

FIGS. 2-13 show various embodiments of a process for forming a semiconductor package;

FIGS. 14a-f show application of the invention in different types of packages; and

FIGS. 15a-b show various embodiments of package interconnects configurations.

### DESCRIPTION

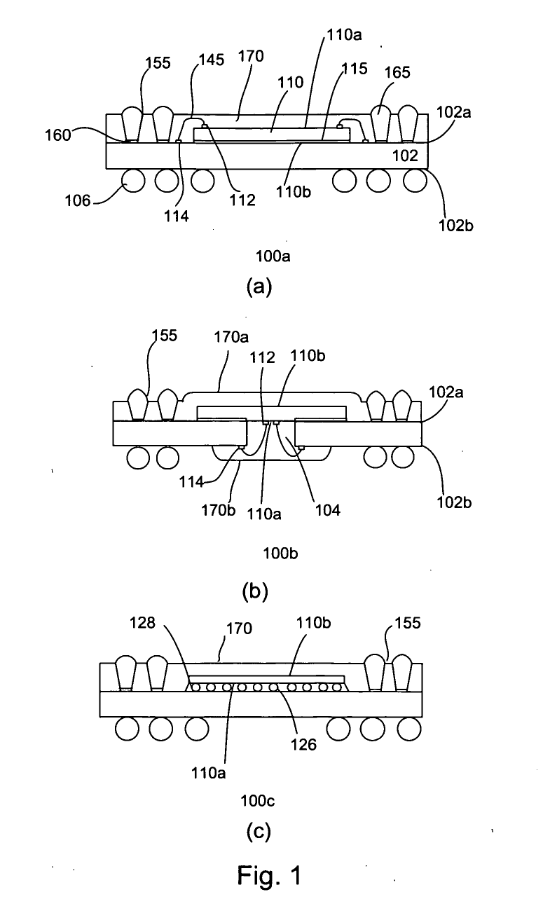

Embodiments generally relate to package structures. In one embodiment, embodiments relate to package-on-package (PoP) structures and method of forming PoP structures. Other types of applications can also be useful. FIGS. 1a-c show cross-sectional views of various embodiments of a die package. Referring to FIG. 1a, the die package 100a includes a carrier or package substrate 102 with top 102a and bottom 102b major surfaces. The substrate can be any type of substrate used for integrated circuit (IC) packages. Various materials, such as Bismaleimide Triazine (BT), polyimide or ceramic can be used to form the substrate. Other types of materials are also useful. Package contacts 106 are disposed on one of the major surfaces. The surface on which the contacts are located is, for example, referred to as the bottom surface. The package contacts can comprise spherical shaped structures or balls arranged in a grid pattern to form a BGA. The balls, for example, comprise solder. Various types of solders can be used, such as lead-based, non lead-based alloys or conductive polymers. Arranging the contacts in other patterns or providing other types of contacts are also useful.

Electrical traces (not shown) are formed on at least the top surface of the substrate. Generally, electrical traces are provided on both the top and bottom surfaces. The traces on the top surface are coupled to the traces on the bottom surface by vias (not shown), which are electrically coupled to package contacts mounted on the bottom surface of the substrate. In one embodiment, bond pads are provided on the electrical traces on the top surface for coupling with the semiconductor die or chip. Providing bond pads on the bottom or on both major surfaces is also useful.

A semiconductor die 110 is mounted on the substrate. The die can be any type of IC. For example, the IC can be a memory device such as a dynamic random access memory (DRAM), a static random access memory (SRAM) and various types of non-volatile memories including programmable read-only memories (PROM) and flash memories, an optoelectronic device, a logic device, a communication device, a digital signal processor (DSP), a microcontroller, a system-on-chip, as well as other types of devices.

As shown in FIG. 1a, the active surface of the die 110a, in one embodiment, is facing away from the substrate. The active surface of the die is provided with die pads 112 or contact regions. The inactive surface 110b of the die is mounted to the substrate using, for example, an adhesive 115. The adhesive, in one embodiment, comprises an insulating adhesive. Various types of adhesives, for example, epoxy, paste, film or tape, can be used.

The die is electrically connected to the substrate by electrical connections such as wires 145. The wires, for example, are attached to die pads of the die and to the bond pads 114 on the top surface of the substrate. As shown, the die comprises die pads located on the periphery of the die. Providing die pads at other locations of the die can also be useful. The package, in one embodiment, includes a cap 170 that encapsulates the die. The cap, for example, comprises a mold compound.

In one embodiment, the top surface of the substrate comprises landing pads 160. The landing pads are used to couple to other packages. For example, the landing pads are coupled to a package stacked above. In one embodiment, the cap 170 includes vias 155 exposing the landing pads. The vias 155 are filled with a conductive material as will be described in the next paragraph. The vias 155, in one embodiment, are predefined in the cap. For example, the vias 155 are predefined by a mold chase in the form of, for example, pillars extending from a top mold chase to the landing pads, thereby resulting in formation of the vias 155 after encapsulation when the mold chase is removed. Other techniques or processes for providing the vias are also useful. The vias, in one embodiment, comprise tapered sidewall profiles. The tapered vias can facilitate uniform filling of the vias and releasibility of the mold chase. The tapered angle of the vias is, but not limited to, about 8-12 degrees. Providing other shaped types of vias or non-tapered sidewall profiles for the vias can also be useful. The via, for example, comprises an upper width of about 0.35 mm and a lower width of about 0.25 mm for a 0.5 mm landing pad pitch package. For a 0.65 mm landing pad pitch, the via, for example, comprises an upper width of about 0.45 mm and a lower width of about 0.35 mm. Other widths can also be useful.

The vias, in one embodiment, are filled with conductive materials 165. The conductive materials can be solder materials such as lead-based, non lead-based alloys or conductive polymers. In one embodiment, the vias are filled with conductive materials and are formed on landing pads overlying the top surface of the substrate. Providing vias filled with conductive materials at other locations of the substrate can also be useful. In one embodiment, a top surface of the conductive material is above a top surface of the cap. The top surface of the conductive material, in one embodiment, is substantially rounded to form ball-shaped package interconnects. The vias that are filled with conductive material can provide electrical connections for attaching another semiconductor package on top of the underlying semiconductor package to reduce or minimize the thickness of the overall package. Furthermore, an air gap can be provided in between the semiconductor packages to improve heat dissipation. The filled vias that are at least partially embedded in mold compound can also reduce warpage especially during package stacking. In an alternate embodiment, a top surface of the conductive material is substantially coplanar with a top surface of the cap. Advantageously, in this embodiment, the coplanarity of the conductive material with the cap can better retain the stacking ability of the package in the event of warpage of the die package. Providing top surface of the cap above the top surface of the conductive material is also useful.

FIG. 1b shows an alternate embodiment of a die package 100b. The die package of FIG. 1b comprises similar arrangement as the die package of FIG. 1a. An opening 104 is provided in the substrate to provide communication from one major surface to the other. In one embodiment, the die has its active surface 110a facing a top surface 102a of the substrate. Sides of the active surface of the die are mounted to the top surface of the substrate using adhesives 115. As shown, the active surface of the die comprises die pads 112 located on a central portion of the die. Similarly, the die is electrically connected to the package by wires 145. The wires are attached to die pads of the die to the bond pads 114 that are located on a bottom surface 102b of the substrate. The package includes a first cap 170a that encapsulates the inactive surface 110b of the die on the top surface of the substrate as shown in FIG. 1b. In an alternate embodiment, the first cap exposes the inactive surface of the die. Exposing the inactive surface of the die facilitates heat dissipation, enhancing thermal performance of the package. A second cap 170b is provided to encapsulate the exposed portion of the die and wires at the bottom surface of the substrate. Similar to the die package of FIG. 1a, a plurality of vias 155, in one embodiment, are predefined in the first cap and filled with conductive materials, providing electrical connections for attaching another semiconductor package on top of it.

Referring to FIG. 1c, a semiconductor package 100c that includes a die in the form of a flip chip in accordance with one embodiment is presented. The flip chip includes an active surface 110a on which conductive bumps 126 are formed. The conductive bumps, for example, comprise solder bumps. Various types of solders, such as lead-based, non lead-based alloys or conductive polymers, can be used to form the conductive bumps. Contact pads (not shown) are disposed on the top surface of the substrate. The contact pads are connected to the package contacts by conductive traces. When the die is mounted onto the substrate, the bumps are mated to the contact pads. Solder paste can be provided on the pads. The solder paste melts during assembly, forming a connection between the pads and conductive bumps of the die.

An underfill 128, such as epoxy, can be provided in the cavity between the die and substrate to encapsulate and protect the conductive bumps. Similar to the arrangements as described for FIGS. 1a-b, a cap 170 is provided to encapsulate the flip chip. In an alternate embodiment, the cap exposes the inactive surface 110b of the die. The cap, in one embodiment, includes a plurality of vias 155 filled with conductive materials, thereby providing electrical connections for attaching another semiconductor package thereon. A top surface of the conductive material, in one embodiment, is above a top surface of the cap. Providing top surface of the conductive material that is coplanar with the top surface of the cap or providing top surface of the cap above the top surface of the conductive material can also be useful.

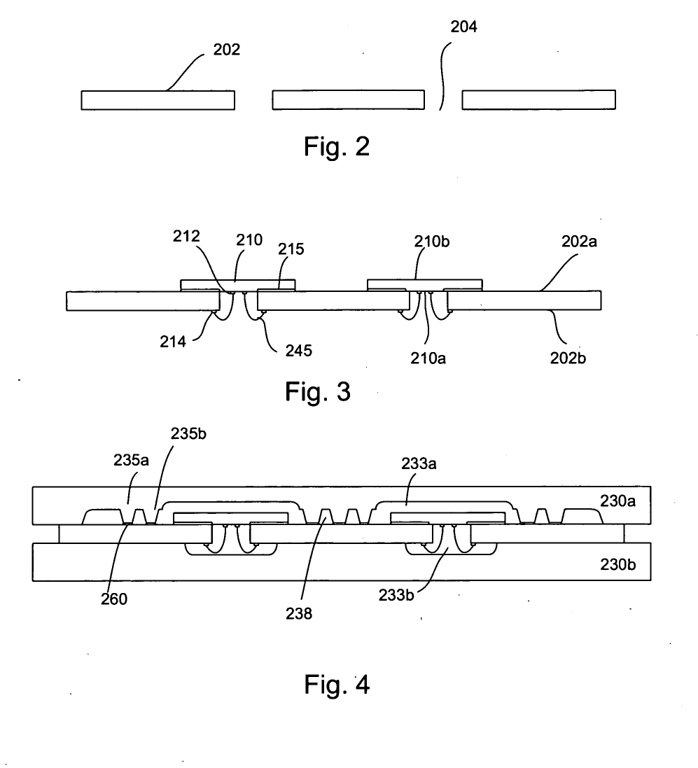

FIGS. 2-13 show various embodiments of a method of forming a semiconductor package. A substrate 202 is provided as shown in FIG. 2. The substrate can be any type of substrate used for IC packages. Various materials, such as Bismaleimide Triazine (BT), polyimide or ceramic can be used to form the substrate. Other types of materials are also useful. The substrate, in one embodiment, comprises an opening 204. The opening, serves as an electrical connection channel, for example, a bond channel for allowing wire bonds to electrically connect a die to the package substrate as shown, for example, in the die package of FIG. 1(b). Providing a substrate without an opening is also useful and would apply for die packages as shown, for example, in FIGS. 1(a) and 1(c).

In one embodiment, the substrate comprises a substrate strip for forming a plurality of packages. The number of packages that can be assembled from the substrate strip is dependent on process requirements, layout design and package size, and hence is not limited to any number. Where a die package of the type shown in FIG. 1(b) is desired, the substrate strip may comprise a plurality of openings. The number of openings corresponds to the number of dies to be attached to the substrate strip. For example, an opening accommodates a die. For illustration purposes the substrate strip comprises first and second openings. It will be appreciated that for ease of description and illustration, the method described herein with reference to FIGS. 2-13 would typically be for die packages of the type shown in FIG. 1(b). As will be readily understood by persons skilled in the art, the method may be extended to die packages of the types shown in FIGS. 1(a) or 1(c). Other types of packages may also be used.

The process continues by attaching dies 210 onto the substrate strip, as shown in FIG. 3. For example, active surfaces 210a of the die are attached to the top surface 202a of the substrate strip. The active surface of the die is provided with die pads 212 or contact regions. In one embodiment, the die pads are located at a central portion of the die. Providing other configuration of die pads may also be useful. The dies are mounted to the substrate using, for example, an adhesive 215. The adhesive, in one embodiment, comprises an insulating adhesive. Various types of adhesives, for example, epoxy, paste, film or tape, can be used.

The die, in one embodiment, is electrically connected to the package substrate by electrical connections such as wires 245. The wires are attached to the die pads of the die to the bond pads 214 that are located on a bottom surface 202b of the substrate. The wires, for example, may comprise gold or copper wires. Providing wires using different types of materials and other types of electrical connection may also be useful.

The substrate comprises landing pads associated with each die. The landing pads, for example, are used to facilitate stacking of packages. For example, the landing pads provide connection to a package stacked above it.

Referring to FIG. 4, the process continues by providing a top 230a and bottom 230b mold chase on the top and bottom surfaces of the substrate. The mold chases are attached to top and bottom surfaces of the substrate strip. The mold chases comprise a plurality of cavities 233a-b in which mold material are injected to encapsulate the dies and wire bonding regions. The top mold chase, in one embodiment, comprises a plurality of pillars 235a-b corresponding to the landing pads 260. The pillars define vias in the cap for filling of conductive materials in a subsequent process. Adjacent pillars, in one embodiment, are separated by a cavity 238, providing area for filling of cap material in subsequent step. The pillars, in one embodiment, are tapered pillars. Providing other shaped types of pillars, such as non-tapered pillars, is also useful. The pillars protect the landing pads from being contaminated by the molding material. The pillars may be a fixed structure attached to the top mold chase or a retractable structure attached to the top mold chase. The retractable pillars can be retracted from the vias prior to removing the mold chase to facilitate removal therefrom.

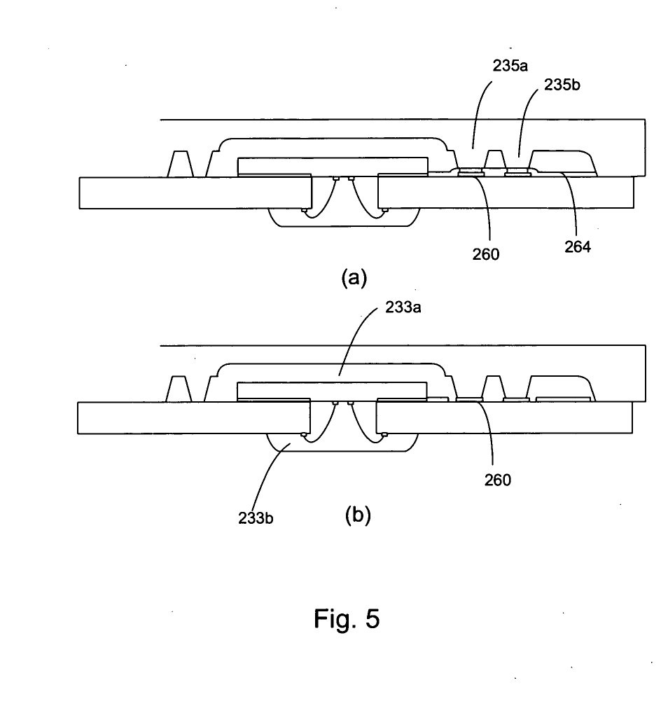

In one embodiment, the substrate comprises a mask layer 264 covering the top surface of the substrate except the landing pads. The mask layer 264 may cover peripheral portions of the landing pads as shown in FIG. 5(a). The mask layer can be provided on the top surface of the substrate prior to attaching the die to the substrate. The mask layer, in one embodiment, comprises mask layer made of solder mask. The pillars of the top mold chase, in one embodiment, are sitting on top of the landing pads such that the mask layer at the peripheral portion of the landing pad creates a small gap between the pillar and the landing pad as shown in FIG. 5(a). Pillars, as shown in FIG. 5a, are used to protect the landing pads from being contaminated by cap material during molding such as transfer molding. In an alternate embodiment as shown in FIG. 5b, the top surface of the substrate comprises mask layer 264 but not covering the landing pads nor the peripheral portions of the landing pads. Accordingly, the pillars are sitting directly on top of the landing pads. The pillars, in one embodiment, are slightly pressing the landing pads to prevent mold resin contamination during molding.

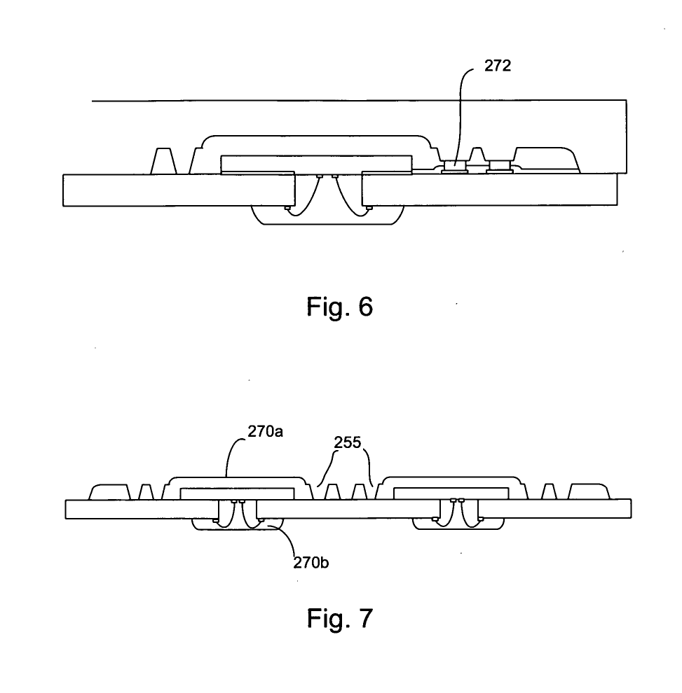

To facilitate easy release of the top mold chase, a non-stick coating may be applied onto the surfaces of the pillars in contact with the mold compound and with the landing pads. The non-stick coating can, for example, comprise Teflon®. Other types of non-stick coating are also useful. The pillars may be coupled to the top mold chase using springs to reduce pressure on the landing pads when the top and bottom mold chases are clamped during molding. FIG. 6 shows another embodiment of the substrate. In one embodiment, conductive bumps 272, for example Cu bumps, can be incorporated into the landing pads of the substrate. Providing other types of bumps is also useful. This helps to achieve better and easier mold release after molding as shorter pillars may be employed for the top mold chase.

The process continues by providing a mold compound to the cavities of the mold chases, forming a first cap 270a and a second cap 270b for the die package as shown in FIG. 7. The mold compound, in one embodiment, comprises epoxy and fillers such as silica fillers, aluminum fillers or the like. Other materials can also be used to form the cap. The mold chases are removed from the package. As can be seen, vias 255 are created in the cap. The vias, in one embodiment, comprise tapered sidewall profiles. The tapered vias can facilitate uniform filling of the vias and releasibility of the mold chase. The tapered angle of the vias is, but not limited to, about 8-12 degrees. Providing other shaped types of vias or non-tapered sidewall profiles for the vias can also be useful. The via, for example, comprises an upper width of about 0.35 mm and a lower width of about 0.25 mm for a 0.5 mm landing pad pitch package. For a 0.65 mm landing pad pitch, the via, for example, comprises an upper width of about 0.45 mm and a lower width of about 0.35 mm. Other widths can also be useful.

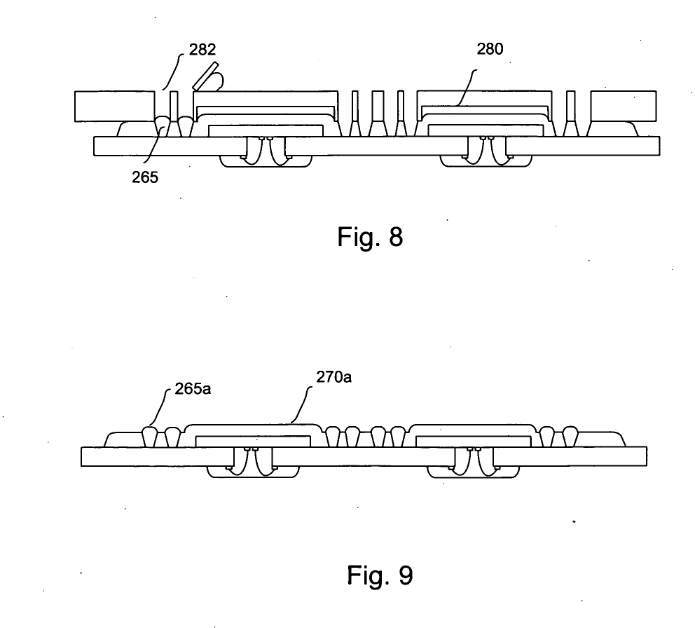

In one embodiment, a stencil 280 is provided on top of the die package as shown in FIG. 8. The stencil comprises openings 282 corresponding to the vias formed. The vias, in one embodiment, are filled up with conductive material 265, for example solders such as lead-based, non lead-based alloys or conductive polymers using stencil printing method. Other techniques and other conductive materials can also be used. The stencil is removed after filling the vias with a conductive material such as solder, as illustrated in FIG. 9. In one embodiment, a top surface 265a of the conductive material is above a top surface 270a of the cap. The top surface of the conductive material, in one embodiment, is substantially rounded, forming ball shaped package interconnects when viewed from top. The vias that are filled with conductive material can provide electrical connections for attaching another semiconductor package on top of the underlying semiconductor package to reduce or minimize the thickness of the overall package and further provide an air gap in between the semiconductor packages, thus improving heat dissipation. The filled vias that are at least partially embedded in mold compound can also reduce warpage especially during package stacking. In an alternate embodiment, a top surface of the conductive material is coplanar with a top surface of the cap. Advantageously, in this embodiment, the coplanarity of the conductive material with the cap can better retain the stacking ability of the package in the event of warpage of the die package. Providing a top surface of the cap above a top surface of the conductive material can also be useful.

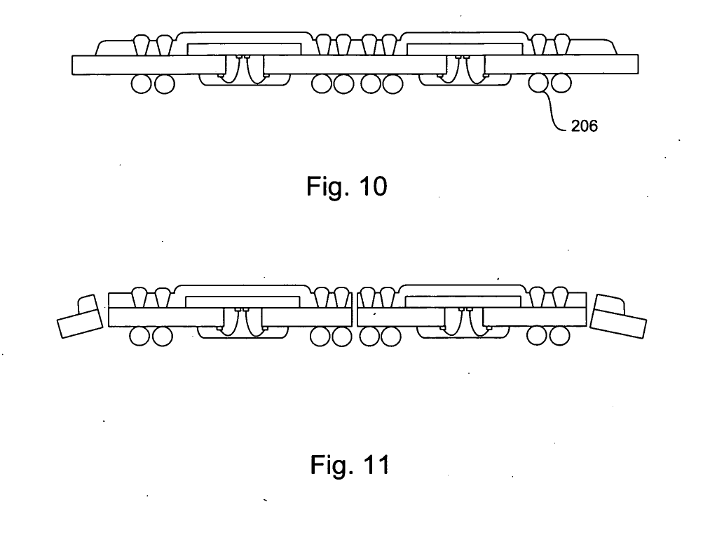

Referring to FIG. 10, package contacts 206 can be disposed on the bottom surface of the substrate. The package contacts can comprise spherical shaped structures or balls arranged in a grid pattern to form a BGA. The balls, for example, comprise solder. Various types of solders can be used, such as lead-based, non lead-based alloys or conductive polymers. Arranging the contacts in other patterns or providing other types of contacts are also useful.

The process continues by singulation using sawing method or equivalents to form individual die package as illustrated in FIG. 11. The individual package in accordance with the invention can be used for forming two or more package stack.

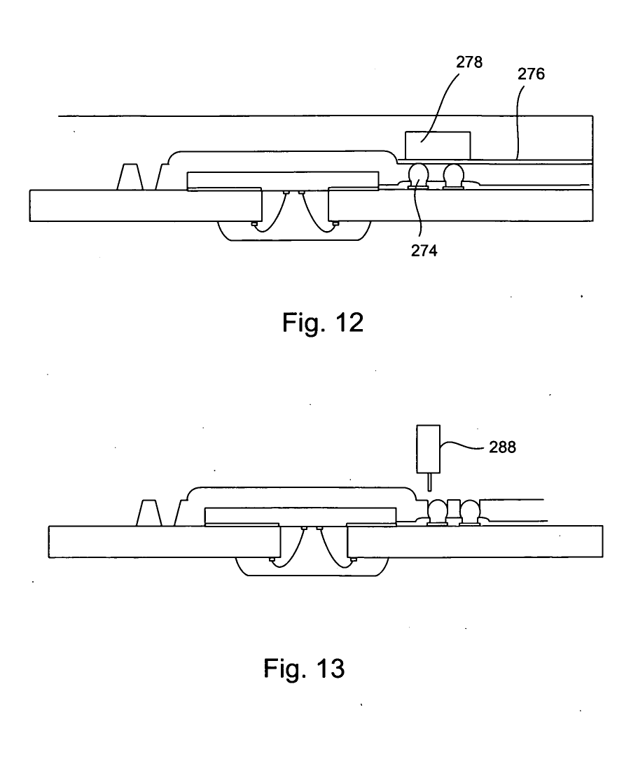

FIGS. 12-13 show an alternate embodiment of a method for forming a semiconductor package. The method is similar to the previous described method except for the following. Instead of using a mold chase with pillars resting on the landing pads as shown and described with reference to FIG. 4 in the previous method, the landing pads are provided with a conductive material 274 as shown in FIG. 12. The conductive material, for example, can be ball-shaped and may be made of solder material. Providing other shaped types of conductive materials is also useful. A mold release film 276 may be provided over the conductive material before clamping the top and bottom mold chases together in preparation for molding. For additional cushioning, a rubber insert 278 or equivalents can be incorporated into the top mold chase to reduce clamping stress on the mold release film 276 and the conductive material.

FIG. 13 shows the semiconductor package when the mold chase is removed. The top ends of the conductive material are exposed while the die, and spaces between the conductive material, are occupied by the mold compound. In one embodiment, to increase or maximize the exposure of the conductive material before package stacking, the width of the vias can be increased, for example, by employing laser ablation using laser beam 288 as shown in FIG. 13. Alternatively, the laser ablation may be used to grind or saw the mold cap together with the conductive material to result in a planar surface comprising a truncated conductive material and the mold cap. These techniques will also provide uniform openings. Other techniques for increasing the openings can also be used.

Yet another method of forming a semiconductor package is described herein. The method is similar to the method described previously except for the following. Instead of using a mold chase with pillars resting on the landing pads as shown and described with reference to FIG. 4 in the previous method, the landing pads are provided with conductive material as shown in FIG. 12. The conductive material, for example, can be ball-shaped and may be made of solder material. Top and bottom mold chases are provided such that the conductive material and die become completely encapsulated in mold compound after encapsulation. The top surface of the mold cap is removed until the conductive material becomes exposed. The removal may be achieved by laser ablation, grinding, sawing or the like. Other techniques can also be useful.

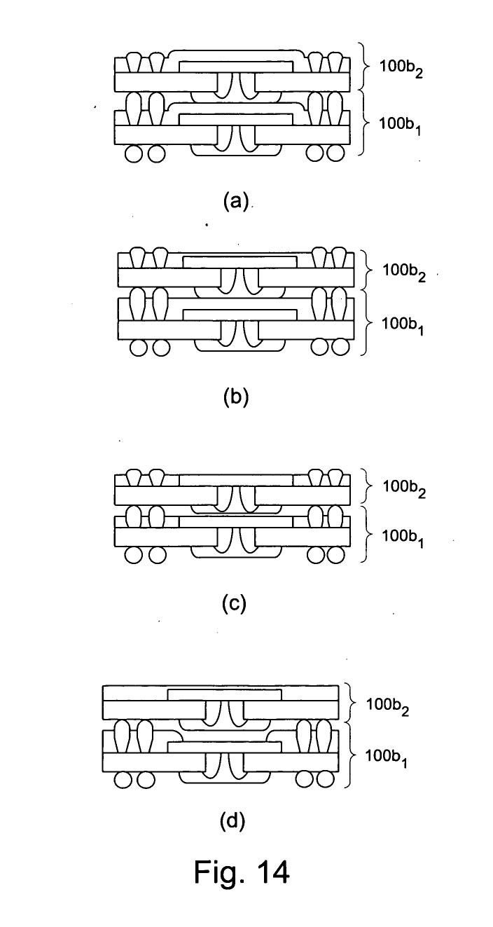

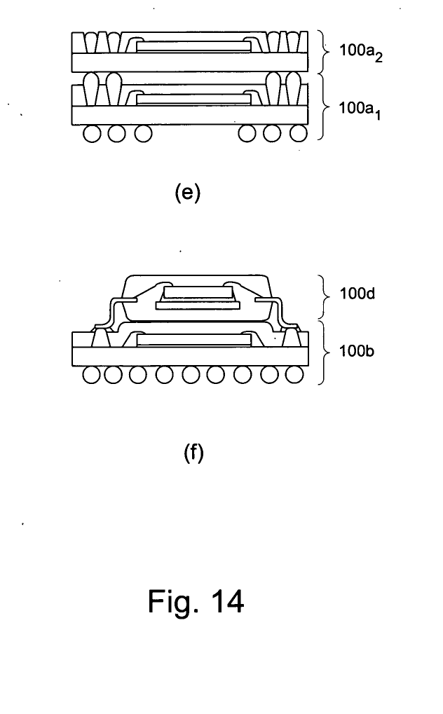

FIGS. 14a-f show application of embodiment of the invention in various types of packages, for example, step package, flat package, exposed die package and leadframe based package such as thin small outline package (TSOP) stacked die package. The invention can also be used for other package types as well. FIG. 14a shows a first die package 100b₁ as previously described in FIG. 1b. The first die package includes a cap having vias filled with conductive material, forming package interconnects for stacking a second die package 100b₂ of the same type on top of the first die package. Stacking different types of packages is also useful. FIGS. 14b-d show stacking of similar die packages as those described for FIG. 14a except that the shapes of the cap are different. The cap of the die packages of FIG. 14b comprises a flat surface covering the entire die. FIG. 14c, on the other hand, shows top surface of the cap being coplanar with top surface of the inactive surface of the die, thus exposing the inactive surface of the die. FIG. 14d shows similar configuration as FIG. 14b except that the cap of the bottom package is partially recessed to expose portions of the inactive surface of the die. FIG. 14e shows stacking of two die packages 100a₁ and 100a₂ that are of the same type as those described in FIG. 1a. The die package as described in FIG. 1b can also be used for attaching a TSOP package 100d as shown in FIG. 14f. Thus, the invention provides flexibility and enables packages of different types to be stacked together.

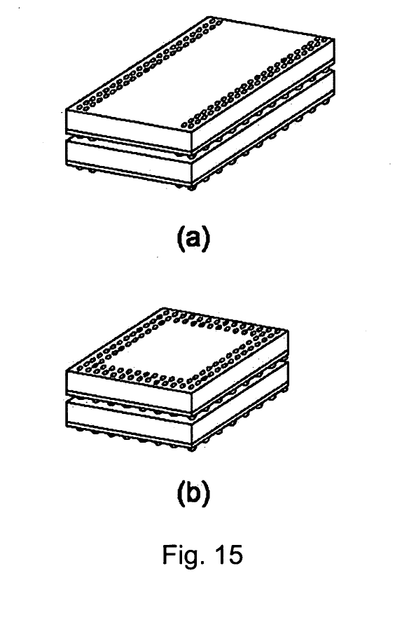

Various package interconnects arrangements, for example, 2 sided solder lands and 4 sided solder lands are shown in FIGS. 15a and 15b respectively. Although two types of package interconnects arrangements are shown in FIGS. 15a-b, it is to be understood that the invention is not limited to only these two arrangements.

The invention describes over-molding the die package and exposing only the ball or package interconnects for package stacking purposes. This way, the package can be molded using conventional map type molding, for example FBGA, and eliminates the need of using direct gate mold. Over-molding the flange area of the substrate or the whole package like FBGA will balance the overall structure of the package and will help to reduce warpage. FBGA top mold chase, in accordance with one embodiment, would have to be modified to incorporate pillars that will create vias on the package cap after molding. The vias along the perimeter of the mold cap in one embodiment coincide with the position of the package interconnects which will later cater for vertical stacking or inter-connect.

Therefore, the package size is smaller than the conventional PoP structure and the landing pad pitch can be reduced to 0.5 mm or less. The feature in the invention also acts as an interposer for stacking of packages with fine ball pitch and low standoff that is not enough to clear the mold cap thickness of the bottom package in conventional PoP. The invention also covers the possibility of using substrate with pre-attached solder balls which eliminate the need of printing solder paste into the vias after mold process.

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

What is claimed is:

1. A semiconductor package comprising:
a substrate having first and second major surfaces;
a plurality of landing pads disposed on the first major surface;
a semiconductor die disposed on the first major surface;
a molded cap disposed on the first surface to encapsulate the die and substrate, wherein the landing pads are covered when the cap is molded; and
package interconnects coupled to the landing pads, wherein the package interconnects are exposed by the cap to facilitate package stacking.

2. The package of claim 1 wherein the landing pads are covered by pillars from a mold chase for molding the package.

3. The package of claim 2 wherein a slick coat is provided on surface of the landing pads to facilitate removal of the pillars.

4. The package claim 1 wherein the landing pads are covered by the package interconnects when the cap is molded.

5. The package of claim 1 wherein covering the landing pads avoids contamination of the landing pads by material of the cap.

6. The package of claim 1 wherein the cap exposes a top surface of the die.

7. A method of forming a semiconductor package comprising:
providing a substrate with first and second major surfaces and a plurality of landing pads on the first major surface;
attaching a die on the first major surface;
forming a cap on the first major surface to encapsulate the die and substrate, wherein the landing pads are covered when the cap is formed; and
providing package interconnects coupled to the landing pads, wherein the package interconnects are exposed by the cap to facilitate package stacking.

8. The method of claim 7 wherein the cap exposes a top surface of the die.

9. The method of claim 7 wherein covering the landing pads avoids contamination by material used to form the cap.

10. The method of claim 7 wherein the package interconnects comprise solder.

11. The method of claim 7 wherein forming the cap comprises:
attaching first and second mold chases to the first and second major surfaces, wherein the first mold chase comprises pillars covering the landing pads;
injecting cap material into a mold formed by the mold chases; and
removing the mold chases, wherein the pillars form vias in the cap which exposes the landing pads.

12. The method of claim 11 wherein the pillars are fixed pillars or retractable pillars.

13. The method of claim 11 wherein the vias are filled with a conductive material to provide the package interconnects.

14. The method of claim 11 wherein the package interconnects comprise solder.

15. The method of claim 11 wherein the cap exposes a top surface of the die.

16. The method of claim 7 wherein forming the cap comprises:
attaching first and second mold chases to the first and second major surfaces, wherein package interconnects are disposed on the landing pads to cover the landing pads;
injecting cap material into a mold formed by the mold chases; and
removing the mold chases to form the cap with package interconnects coupled to the landing pads.

17. The method of claim 16 wherein removing the mold chases forms a cap which exposes the package interconnects.

18. The method of claim 16 where a surface of the cap is processed to expose the package interconnects.

19. A method of forming a semiconductor package comprising:
providing a substrate with first and second major surfaces and a plurality of landing pads on the first major surface;
attaching a die on the first major surface;
forming a cap on the first major surface to encapsulate the die and substrate, wherein the cap comprises vias exposing the landing pads; and
filling the vias with a conductive material to form package interconnects on the landing pads, wherein top surfaces of the package interconnects are exposed by the cap to facilitate package stacking.

20. The method of claim 19 wherein forming the cap comprises:
attaching first and second mold chases to the first and second major surfaces, wherein the first mold chase comprises pillars covering the landing pads;
injecting cap material into a mold formed by the mold chases; and
removing the mold chases, wherein the pillars form the vias in the cap which exposes the landing pads.
